(19) United States
(12) Patent Application Publication
(10) Pub. No.: US 2018/0033886 A1
(43) Pub. Date: Feb. 1, 2018

(54) Semiconductor Devices, Electrical Devices and Methods for Forming a Semiconductor Device

(71) Applicant: Infineon Technologies Austria AG, Villach (AT)

(72) Inventors: Anton Mauder, Kolbermoor (DE); Armin Willmeroth, Friedberg (DE)

(21) Appl. No.: 15/660,426

(22) Filed: Jul. 26, 2017

(30) Foreign Application Priority Data
Jul. 27, 2016 (DE) 102016113846.0

(51) Int. Cl. H01L 29/78; H03K 17/687; H01L 21/74; H01L 21/266; H01L 29/10; H01L 29/06

(52) U.S. Cl. CPC H01L 29/7815; H01L 29/1087; H01L 29/0696; H01L 29/1095; H01L 29/0634; H01L 21/743; H01L 21/266; H03K 17/6871

(57) ABSTRACT

A semiconductor device includes a plurality of compensation regions arranged in a semiconductor substrate of the semiconductor device. The compensation regions of the plurality of compensation regions have a first conductivity type. The semiconductor device also includes a plurality of drift region portions of a drift region of a vertical electrical element arrangement arranged in the semiconductor substrate of the semiconductor device. The drift region has a second conductivity type. Drift region portions of the plurality of drift region portions and compensation regions of the plurality of compensation regions are arranged alternatingly in a lateral direction. The semiconductor device further includes a tap electrode structure in contact with a tap portion of the drift region at a front side surface of the semiconductor substrate. The tap portion is located laterally between two neighboring compensation regions of the plurality of compensation regions.

### TECHNICAL FIELD

Embodiments relate to concepts for power semiconductor devices and in particular to semiconductor devices, electrical devices and methods for forming semiconductor devices.

### BACKGROUND

Monitoring voltages or currents is desired for a large variety of applications. For example, the measurement and monitoring of the forward voltage of power transistors in switched-mode power supplies is a difficult task. Other applications may need the generation of a start-up current for power up devices.

### SUMMARY

There may be a demand to provide an improved concept for semiconductor devices, which enables monitoring voltages or currents or providing start-up currents.

Some embodiments relate to a semiconductor device comprising a plurality of compensation regions arranged in a semiconductor substrate of the semiconductor device. The compensation regions of the plurality of compensation regions comprise a first conductivity type. Further, the semiconductor device comprises a plurality of drift region portions of a drift region of a vertical electrical element arrangement arranged in the semiconductor substrate of the semiconductor device. The drift region comprises a second conductivity type. Further, drift region portions of the plurality of drift region portions and compensation regions of the plurality of compensation regions are arranged alternatingly in a lateral direction. Additionally, the semiconductor device comprises a tap electrode structure in contact with a tap portion of the drift region at a front side surface of the semiconductor substrate. Further, the tap portion is located laterally between two neighboring compensation regions of the plurality of compensation regions. Additionally, the tap electrode structure is implemented without resistive connection to the plurality of compensation regions.

Some embodiments relate to a semiconductor device comprising an insulated-gate field effect transistor and a junction field effect transistor. A drain region of the insulated-gate field effect transistor and a drain region of the junction field effect transistor are electrically connected to a drain contact interface for connecting the semiconductor device to an external load. Further, at least one source region of the insulated-gate field effect transistor is electrically connected to a gate region of the junction field effect transistor. Additionally, a tap electrode structure is electrically connected to a source region of the junction field effect transistor.

Some embodiments relate to a method for forming a semiconductor device. The method comprises forming a plurality of compensation regions arranged in a semiconductor substrate. The compensation regions of the plurality of compensation regions comprise a first conductivity type. Further, a plurality of drift region portions of a drift region of a vertical electrical element arrangement is arranged in the semiconductor substrate. The drift region comprises a second conductivity type. Additionally, drift region portions of the plurality of drift region portions and compensation regions of the plurality of compensation regions are arranged alternatingly in a lateral direction. Further, the method comprises forming a tap electrode structure in contact with a tap portion of the drift region at a front side surface of the semiconductor substrate. The tap portion is located laterally between two neighboring compensation regions of the plurality of compensation regions.

Those skilled in the art will recognize additional features and advantages upon reading the following detailed description and on viewing the accompanying drawings.

### BRIEF DESCRIPTION OF THE FIGURES

Some embodiments of apparatuses and/or methods will be described in the following by way of example only, and with reference to the accompanying figures, in which:

FIG. 1 shows a schematic cross section of a semiconductor device:

FIG. 2 shows a schematic cross section of another semiconductor device:

FIG. 3 shows a schematic profile of a potential at a tap electrode structure of a semiconductor device;

FIG. 4a shows a schematic vertical potential distribution within the semiconductor substrate of a semiconductor device;

FIG. 4b shows a detail of the vertical potential distribution shown in FIG. 4a:

FIG. 5 shows a circuit diagram of a semiconductor device;

FIG. 6 shows a schematic illustration of an electrical device;

FIG. 7 shows a schematic illustration of another electrical device; and

FIG. 8 shows a flow chart of a method for forming a semiconductor device.

### DETAILED DESCRIPTION

Various example embodiments will now be described more fully with reference to the accompanying drawings in which some example embodiments are illustrated. In the figures, the thicknesses of lines, layers and/or regions may be exaggerated for clarity.

Accordingly, while example embodiments are capable of various modifications and alternative forms, embodiments thereof are shown by way of example in the figures and will herein be described in detail. It should be understood, however, that there is no intent to limit example embodiments to the particular forms disclosed, but on the contrary, example embodiments are to cover all modifications, equivalents, and alternatives falling within the scope of the disclosure. Like numbers refer to like or similar elements throughout the description of the figures.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art. However, should the present disclosure give a specific meaning to a term deviating from a meaning commonly understood by one of ordinary skill, this meaning is to be taken into account in the specific context this definition is given herein.

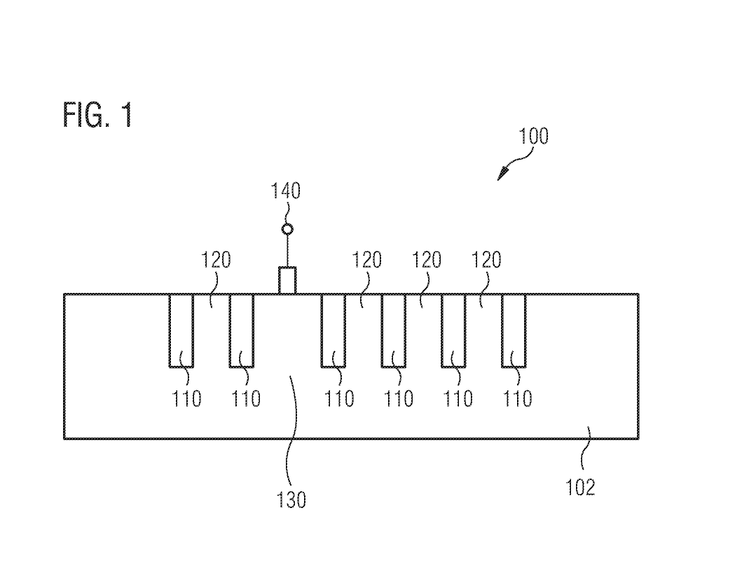

FIG. 1 shows schematic cross section of a semiconductor device 100 according to an embodiment. The semiconductor device 100 comprising a plurality of compensation regions 110 arranged in a semiconductor substrate 102 of the semiconductor device 100. The compensation regions 110 of the plurality of compensation regions 110 comprise a first conductivity type. Further, the semiconductor device 100 comprises a plurality of drift region portions 120 of a drift region of a vertical electrical element arrangement arranged in the semiconductor substrate 102 of the semiconductor device 100. The drift region comprises a second conductivity type. Further, drift region portions 120 of the plurality of drift region portions 120 and compensation regions 110 of the plurality of compensation regions 110 are arranged alternatingly in a lateral direction. Additionally, the semiconductor device 100 comprises a tap electrode structure 140 in contact with a tap portion 130 of the drift region at a front side surface of the semiconductor substrate 102. Further, the tap portion 130 is located laterally between two neighboring compensation regions 110 of the plurality of compensation regions 110. Additionally, the tap electrode structure 140 is implemented without resistive connection to the plurality of compensation regions.

By implementing a tap contact to a portion of a drift region of a vertical electrical element arrangement between two compensation regions, a voltage or current can be tapped at the front side surface of the semiconductor substrate. The voltage occurring at the tap contact may be proportional or nearly equal to a voltage at a back side of the semiconductor substrate in a conductive state of the vertical electrical element arrangement. In this way, monitoring voltages or currents or providing start-up currents may be enabled. For example, a very early detection of an overload situation or a critical voltage drop over the vertical electrical element arrangement may be enabled by monitoring a voltage tapped between two compensation regions. Alternatively or additionally, a start-up current for powering an electrical device or circuit in a start-up phase may be provided at the tap contact.

The tap electrode structure 140 may be implemented within one or more electrical conductive layers above the semiconductor substrate 102. For example, the tap electrode structure 140 comprises one or more lateral wiring lines and one or more vertical connections (e.g. vias) for electrically connecting the tap portion 130 to a tap contact interface (e.g. pad) of the semiconductor interface to enable a connection to an external electrical device or for electrically connecting the tap portion 130 to a circuit (e.g. control circuit or start-up circuit) on the semiconductor substrate 102 of the semiconductor device 100. The tap electrode structure 140 may be connected to a tap contact pad electrically insulated (without resistive connection) from a source contact pad, for example. The tap electrode structure 140 may comprise or consist of aluminum, copper, tungsten and/or poly silicon and/or an alloy of aluminum, copper, tungsten and/or poly silicon. The tap electrode structure 140 is in contact with the semiconductor substrate 102 at a tap contact area implementing a tap contact to the tap portion 130 of the semiconductor substrate 102. The tap portion 130 may comprise a highly doped surface doping region to implement an ohmic contact between the tap electrode structure 140 and the tap portion 130.

The tap electrode structure 140 is implemented without resistive connection to the plurality of compensation regions (e.g. electrically insulated from an electrode structure electrically connecting the plurality of compensation regions, for example, a source electrode structure). For example, the tap electrode structure 140 may be implemented without resistive (ohmic) connection to a source electrode structure (source wiring structure) connected to source doping regions of transistor arrangement (e.g. source regions of a plurality of transistor cells of a transistor arrangement) so that the electrode structure 140 may be electrically insulated from the source electrode structure.

The potential arising in the tap portion 130 and occurring at the tap contact in a conductive state of the vertical electrical element arrangement is approximately equal to a potential at a back side surface of the semiconductor substrate 102 and/or within the drift region portions 120, since the tap portion 130 is part of the drift region (e.g. all portions of the drift region comprise the second conductivity type) and there may be almost no current flowing through this drift region portion (139). Therefore, a voltage occurring at the tap electrode structure 140 may be substantially equal or proportional to a voltage drop between the front side surface and a back side surface of the semiconductor substrate 102 in a conductive state or on-state of the vertical electrical element arrangement. For example, the drift region may extend to the back side surface of the semiconductor substrate 102 or a highly doped semiconductor bulk region (comprising the second conductivity type) may be located between the drift region and the back side surface of the semiconductor substrate 102 having an insignificant influence to the voltage drop. The voltage occurring at the tap electrode structure 140 may be monitored or repeatedly sensed to detect an unexpected change of the voltage (e.g. to detect an overload situation).

For example, at least the vertical electrical element arrangement (e.g. a vertical diode arrangement or a vertical transistor arrangement) of the semiconductor device 100 is a compensation or superjunction structure enabling a control and/or conduct and/or block a current flow between the front side of the semiconductor device and a backside of the semiconductor device. The vertical electrical element arrangement comprises drift region portions 120 and compensation regions 110 arranged alternatingly in at least one lateral direction within a cell region of the semiconductor substrate. For example, the plurality of compensation regions 110 may extend into a depth of more than 10 μm (or more than 30 μm or more than 50 μm). For example, the compensation regions 110 may be strip-shaped (e.g. pillar-shaped or column-shaped in a cross section). Further, the drift region portions 120 may be strip-shaped as well. For example, a number of drift region portions 120 and a number of compensation region 110 arranged alternatingly is larger than 50 (or larger than 100 or larger than 500).

For example, the plurality of compensation regions and/or the plurality of drift region portions 120 may be regions of the semiconductor substrate 102 comprising a stripe-shaped geometry in a top view of the semiconductor substrate 102 of the semiconductor device 100. A stripe-shape may be a geometry extending in a first lateral direction significantly farther than in an orthogonal second lateral direction. For example, the compensation regions of the plurality of compensation regions and/or the drift region portions 120 of the drift region may comprise a lateral length of more than 10× (or more than 50× or more than 100×) a lateral width of the compensation regions of the plurality of compensation regions 110 and/or the plurality of drift region portions 120. For example, the lateral length of a compensation region 110 and/or a drift region portion 120 may be the largest lateral extension of the compensation region 110 and/or the drift region portion 120 and the lateral width of a compensation region 110 and/or a drift region portion 120 may be a shortest lateral dimension of the compensation region and/or the drift region portion. For example, the plurality of compensation regions 110 and/or the plurality of drift region portions 120 may comprise a vertical extension larger than the lateral width and shorter than the lateral length.

Compensation structures or superjunction structures may be based on mutual compensation of at least a part of the charge of n- and p-doped areas in the drift region. For example, in a vertical transistor, p- and n-stripes (drift region portions and compensation regions) may be arranged in pairs in a cross section of the semiconductor substrate. For example, the compensation regions 110 may comprise a laterally summed number of dopants per unit area of the first conductivity type deviating from a laterally summed number of dopants per unit area of the second conductivity type comprised by the drift region portions by less than +/−25% of the laterally summed number of dopants per unit area of the first conductivity type comprised by the compensation regions 110 within the cell region.

For example, a compensation region 110 of the plurality of compensation regions 110 comprises a laterally summed number of dopants per unit area of the first conductivity type deviating from half of a laterally summed number of dopants per unit area of the second conductivity type comprised by two drift region portions 120 located adjacent to opposite sides of the strip-shaped compensation region by less than +/−25% (or less than 15%, less than +/−10%, less than +/−5%, less than 2% or less than 1%) of the laterally summed number of dopants per unit area of the first conductivity type comprised by the compensation region. The lateral summed number of dopants per unit area may be substantially constant or may vary for different depths. The lateral summed number of dopants per unit area may be equal or nearly equal to a number of free charge carriers within a compensation region 110 or a drift region portion 120 to be compensated in a particular depth, for example.

For example, the compensation regions 110 and the drift region portions 120 may comprise an average doping concentration between 1*10¹⁶ cm³ and 1*10¹⁷ cm³ (or between 2*10⁶ cm⁻³ and 5*10¹⁶ cm⁻³).

For example, the drift region comprises additionally a buffer region or buffer layer (or base layer) located below the compensation regions 110. For example, the buffer region or buffer layer may be located vertically between the bottoms of the compensation regions 110 and a back side surface of the semiconductor substrate or a highly doped bulk semiconductor region (e.g. average doping concentration of more than 1*10¹⁸ cm⁻³ or more than 1*10¹⁹ cm⁻³ and a thickness between 5 μm and 200 μm). The buffer region or buffer layer may extend laterally along the whole cell region of the vertical electrical element arrangement. An average doping concentration of the buffer region or buffer layer may be less than 50% of an average doping concentration of the drift region portions 120. For example, the buffer region or buffer layer may comprise an average doping concentration between 1*10¹⁵ cm⁻³ and 1*10¹⁶ cm⁻³ (or between 3*10¹⁵ cm⁻³ and 6*10¹⁵ cm⁻³). The buffer region or buffer layer may comprise a thickness between 5 μm and 50 μm (or between 10 μm and 30 μm).

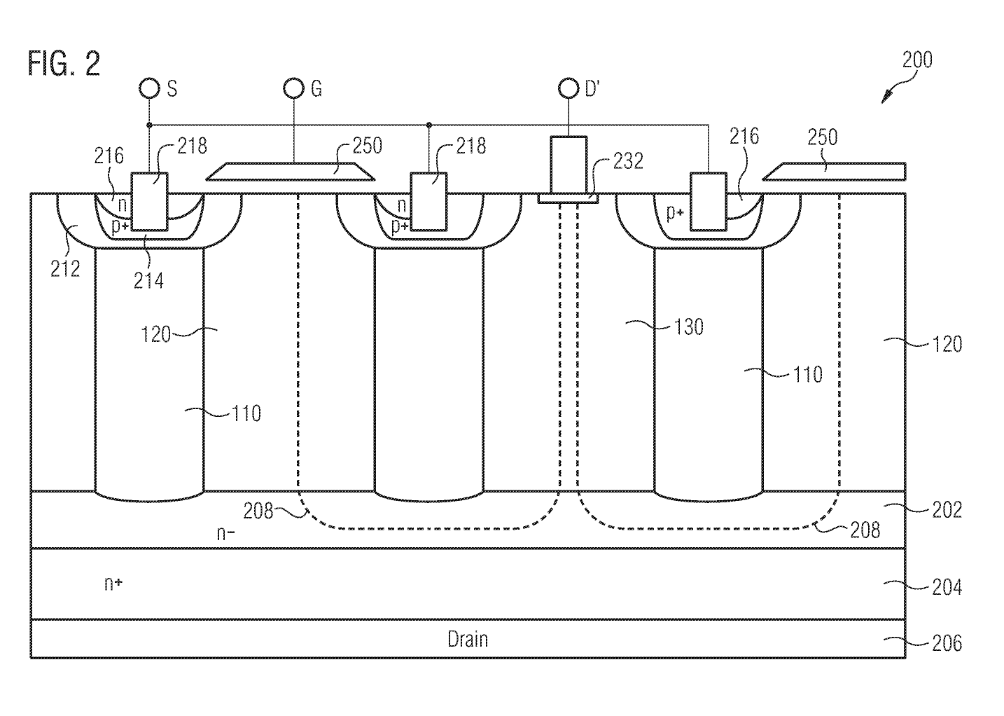

For example, the two compensation regions 110 of the plurality of compensation regions 110 neighboring the tap portion 130 may comprise a (minimal) lateral distance to each other larger than a distance of other compensation regions of plurality of compensation regions 110 (e.g. as indicated in FIG. 1) or may comprise a same (minimal) lateral distance to each other larger as other compensation regions of plurality of compensation regions 110 (e.g. as indicated in the example shown in FIG. 2).

A region comprising the first conductivity type may be a p-doped region (e.g. caused by incorporating aluminum ions or boron ions) or an n-doped region (e.g. caused by incorporating antimony ions, nitrogen ions, phosphor ions or arsenic ions). Consequently, the second conductivity type indicates an opposite n-doped region or p-doped region. In other words, the first conductivity type may indicate a p-doping and the second conductivity type may indicate an n-doping or vice-versa.

The semiconductor substrate 102 may comprise a cell region laterally surrounded by an edge termination region. The cell region may be a region of the semiconductor substrate 102 used to conduct more than 90% of a current through the semiconductor substrate 102 in an on-state or conducting state of the vertical electrical element arrangement. The edge termination region may be located between an edge of the semiconductor substrate 102 and the cell region in order to support or block or reduce or dissipate a maximal voltage applied between the front side surface of the semiconductor substrate 102 and a back side surface of the semiconductor substrate 102 within the cell region laterally towards the edge of the semiconductor substrate 102. For example, the plurality of drift region portions 120 of the drift region of the vertical electrical element arrangement is arranged within the cell region of the semiconductor substrate 102 of the semiconductor device 100.

The semiconductor substrate 102 of the semiconductor device 100 may be a silicon substrate. Alternatively, the semiconductor substrate 102 may be a wide band gap semiconductor substrate having a band gap larger than the band gap of silicon (1.1 eV). For example, the semiconductor substrate 102 may be a silicon carbide (SiC)-based semiconductor substrate, or gallium arsenide (GaAs)-based semiconductor substrate, or a gallium nitride (GaN)-based semiconductor substrate. The semiconductor substrate 102 may be a semiconductor wafer or a semiconductor die.

For example, the vertical direction and a vertical dimension or thicknesses of layers may be measured orthogonal to a front side surface of the semiconductor substrate 102 and a lateral direction and lateral dimensions may be measured in parallel to the front side surface of the semiconductor substrate 102.

The vertical electrical element arrangement may be an electrical structure enabling a vertical current flow through the semiconductor substrate 102 in a conductive state of the vertical electrical element arrangement. The vertical electrical element arrangement may be a vertical diode arrangement or a vertical transistor arrangement (e.g. a metal-oxide-semiconductor field effect transistor or insulated-gate-bipolar transistor).

The semiconductor device 100 may be a power semiconductor device. A power semiconductor device or an electrical structure (e.g. transistor structure or diode structure) of the power semiconductor device may have a breakdown voltage or blocking voltage of more than 10V (e.g. a breakdown voltage of 10 V, 20 V or 50V), more than 30V, more than 100 V (e.g. a breakdown voltage of 200 V, 300 V, 400V or 500V) or more than 500 V (e.g. a breakdown voltage of 600 V, 700 V, 800V or 1000V) or more than 1000 V (e.g. a breakdown voltage of 1200 V, 1500 V, 1700V, 2000V, 3300V or 6500V), for example.

For example, the tap portion 130 and the neighboring compensation regions 110 implement a junction field effect transistor structure. In this way, the voltage occurring at the tap electrode structure 140 may be kept low even in a blocking state of the vertical electrical element arrangement with a high voltage applied to the vertical electrical element arrangement, since the compensation regions 110 neighboring the tap portion 130 may deplete the tap portion 130 similar to the depletion of the drift region portions 120 during switch-off. For example, the tap portion 130 of the drift region and the neighboring compensation regions 110 of the plurality of compensation regions 110 may be implemented so that a voltage occurring at the tap electrode structure 140 in a blocking state of the vertical electrical element arrangement is less than 5% (or less than 10%, less than 2% or less than 1%) of a blocking state applied or occurring in the blocking state and/or less than 30V (or less than 20V or less than 10V).

The voltage range occurring at the tap electrode structure 140 may be adjusted in various ways. For example, a maximal voltage at the tap contact may be influenced by a lateral width of the tap portion 130 at the surface of the semiconductor device 102 and/or in a depth of the compensation regions 110.

For example, a lateral width of a drift region portion 120 of the plurality of drift region portions 120 of the drift region measured at a measurement depth of half a depth of a compensation region 110 of the plurality of compensation regions 110 may differ from (e.g. may be larger than or less than) a lateral width of the tap portion 130 of the drift region measured at the measurement depth by more than 10% (or more than 20% or more than 50%) of the lateral width of the tap portion 130 of the drift region measured at the measurement depth. The maximal voltage occurring at the tap region 130 may be higher, if the lateral width of the tap region 130 is larger, and may be lower, if the tap region 130 is narrower.

Additionally or alternatively, a lateral width of a drift region portion 120 of the plurality of drift region portions 120 of the drift region measured at the front side surface of the semiconductor substrate 102 may differ from (e.g. may be larger than or less than) a lateral width of the tap portion 130 of the drift region measured at the front side surface of the semiconductor substrate 102 by more than 10% (or more than 20% or more than 50%) of the lateral width of the tap portion 130 of the drift region measured at the front side surface of the semiconductor substrate 102. For example, the lateral widths at the front side surface of the semiconductor substrate 102 may be set by a width of body doping region of the vertical electrical element arrangement. The maximal voltage occurring at the tap region 130 may be higher, if the lateral width of the tap region 130 is larger at the front side surface, and may be lower, if the tap region 130 is narrower at the front side surface.

Further, the maximal voltage at the tap contact may be influenced by a doping concentration of the tap region 130 close to the surface. Regions with lower doping concentrations may be depleted earlier.

For example, a doping concentration within a drift region portion 120 of the drift region measured at a source depth equal to a depth of a source doping region of the vertical electrical element arrangement may be larger (or lower) than a doping concentration within the tap portion 130 of the drift region measured at the source depth (e.g. by more than 10% or more than 50% of the doping concentration within the tap portion). For example, the depth of the source doping region may be between 500 nm and 2 μm.

For example, the vertical electrical element arrangement is a vertical field effect transistor arrangement. In this example, the vertical electrical element arrangement may comprise one or more source regions, one or more body regions and one or more gates controlling a current between the one or more source regions and the drift region portion 120 through the one or more body regions. A source electrode structure may be electrically connected (ohmic) to the one or more source regions at the front side of the semiconductor substrate 102 and to a source contact interface (e.g. source pad) of the semiconductor device. The source electrode structure is electrically insulated (e.g. implemented without resistive connection) from the tap electrode structure. Additionally, the source electrode structure may be electrically connected (ohmic) to the one or more body regions. Furthermore, the source electrode structure may be electrically connected (ohmic) to the plurality of compensation regions. Additionally, the vertical field effect transistor arrangement may comprise a gate electrode structure electrically connected (ohmic) to the one or more gates of the vertical field effect transistor arrangement. For example, the vertical field effect transistor arrangement is implemented without a gate for controlling a current through the tap portion 130 of the drift region. In this way, the tap region 130 does not significantly contribute to a current flow controlled by the vertical field effect transistor arrangement except for an insignificant current through the tap contact. For example, the current conducted by the tap region 130 may be less than 10% (or less than 1% or less than 0.1%) of a current conducted by a drift region portion 120 in an on-state or conductive state of the vertical field effect transistor arrangement.

For example, the tap electrode structure 140 is electrically insulated from the source electrode structure of the vertical field effect transistor arrangement and electrically insulated from the gate electrode structure of the vertical field effect transistor arrangement.

FIG. 2 shows a schematic cross section of a semiconductor device 200 according to an embodiment. The implementation of the semiconductor device 200 is similar to the implementation of the semiconductor device shown in FIG. 1. The semiconductor device 200 comprises vertical field effect transistor arrangement. The vertical field effect transistor arrangement comprises a plurality of source regions 216, a plurality of body regions 212 (including each a highly doped contact portion 214), a plurality of compensation regions 110, a plurality of drift region portions 120 of a drift region and a plurality of gates 250. The gates are connected to a common gate electrode structure G. The plurality of source regions 216 (e.g. comprising the second conductivity type with a doping concentration of more than 1*10¹⁹ cm⁻³ or above 5*10¹⁹ cm⁻³), the plurality of body regions 212 (e.g. comprising the first conductivity type with a doping concentration between 5*10¹⁶ cm⁻³ and 1*10 cm⁻³ and reaching into depth between 2 μm and 3 μm) and the plurality of compensation regions 110 are short cut and connected to a common source electrode structure S by contact structures within contact trenches 218. Further, the semiconductor device 200 comprises a tap electrode structure D′ connected to a tap region 130 of the drift region. A highly doped surface portion 232 of the tap portion 130 enables an ohmic contact between the tap electrode structure D′ and the tap portion 130. Further, the drift region comprises a buffer layer 202 located below the compensation regions 110. Additionally, a highly doped bulk semiconductor layer 204 may be arranged between the drift region and a back side drain metallization 206.

FIG. 2 shows an example of a structure with drain-sense-terminal D′. For example, FIG. 2 shows a structure for implementing a drain sense terminal which—in case of high-impedance tapping of the potential at the point D′—may limit the voltage at point D′ to a value which may approximately correspond to the lateral depletion voltage between p- and n-columns.

FIG. 2 shows a simplified illustration of the boundary of the space charge zone 208 in the n-column if a positive drain source voltage is applied (e.g. illustrated without a current flow and in case of a homogeneous doping of the columns). For example, as soon as the space charge zones 208 contact each other, the pin D′ (tap contact) connected with high impedance is decoupled from the drain potential and remains on its (fixed) potential in the range of, e.g., a few volts to a few 10V. Holes thermally generated in the off-state case flow off via the p-columns in the direction of the source thermally generated electrons flow off in the direction of the drain, for example. The flowing (low) blocking current may have no (significant) impact on the potential at point D′ and may be particularly not integrated.

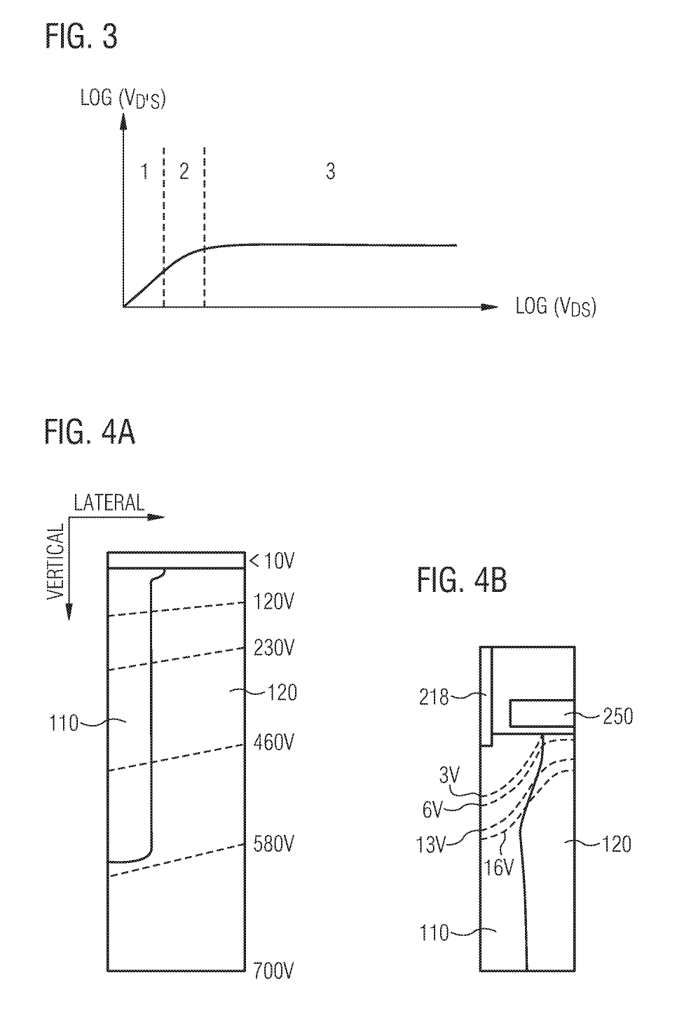

Overall, a potential profile may result at point D′ (at the tap contact) as illustrated in FIG. 3 in which three areas may be distinguished. In area 1, the drain voltage may be provided 1:1 or nearly 1:1 (e.g. neglecting voltage drop between drain and tap contact, while tap portion is not depleted) at terminal D′. This area may be used for more precise measuring purposes. In area 2, the pinching off begins, which is why the voltage increase slows down at terminal D′, before terminal D′ is completely pinched off in area 3 and its potential only increases slightly, if at all, for example. The areas 2 and 3 may be used for the detection of any overload occurrence at the transistor, e.g., a short. FIG. 3 shows an example of a qualitative profile of the potential V_{DS} at the terminal D′ depending on the potential V_{DS} at the terminal D (drain terminal), both in relation to the source potential.

For example, as the area underneath D′ is not required for the current flow, the lateral depletion voltage of the relevant n-compensation area (tap portion) may be reduced by slightly modifying the n-compensation doping close to the surface (e.g. the doping is reduced) so that the maximum potential applied at D′ may be reduced even further. Alternatively or additionally, the body areas in this region may be broaden, so that the potential close to D′ may be further reduced.

For example, in a super junction transistor having a stripe structure, a stripe may therefore be executed without a source area. For example, this may be a stripe which runs through (below) the gate pad or underneath a distribution structure for the gate potential (e.g. which are not used to carry the load current in a power transistors). In this way, the space consumption for the measuring structure may be significantly reduced and may be even limited to the area of the contact pad (of the tap electrode structure).

In a switched-on transistor, the potential applied at D′ might not exactly correspond to the drain potential as the voltage drop in the buffer or base layer 204 (e.g. low doped portion of the drift region) is not carried along, for example. In case of a significant extension of the base layer, the occurring error may be corrected in the controller (e.g. circuit connected to the tap electrode structure and using the sense signal). For example, it may be done with low effort, as the base layer may comprise a constant doping and may have no depletion effects, in contrast to the super junction region.

For example, the terminal D′ may also be used as a current source for a start-up function as it may be a normal ON-structure.

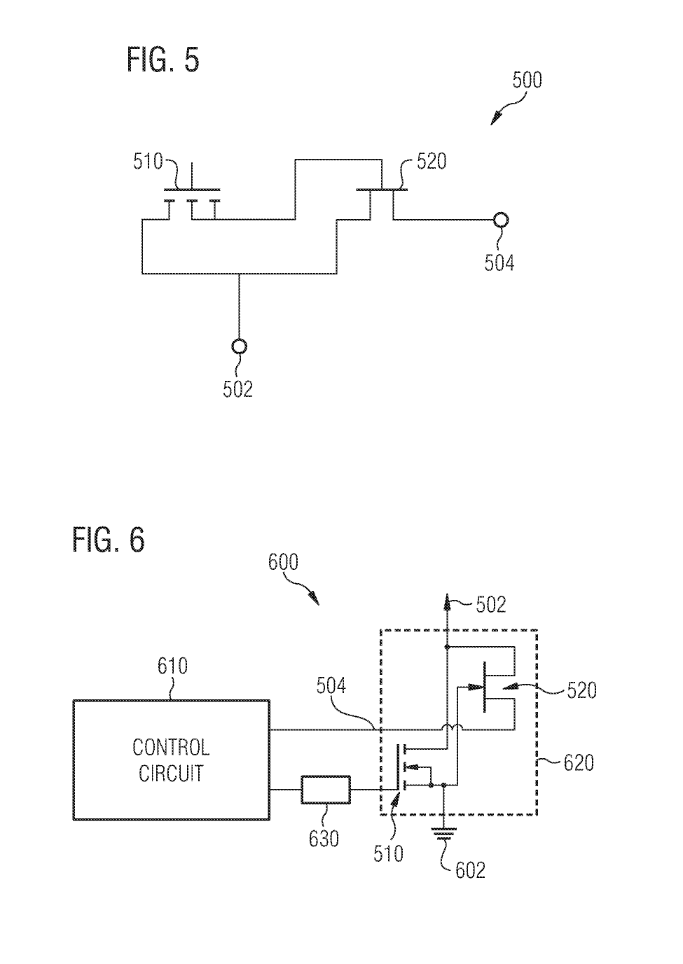

More details and aspects are mentioned in connection with the embodiments described above or below. The embodiment shown in FIG. 2 may comprise one or more optional additional features corresponding to one or more aspects mentioned in connection with the proposed concept or one or more embodiments described above (e.g. FIG. 1) or below (e.g. FIG. 5-8).

FIG. 4a shows a schematic vertical potential distribution within the semiconductor substrate of a semiconductor device in a blocking case. The potential below the gate contact remains there at below 10V, for example. If a corresponding contact D′ (tap contact) is integrated (e.g. instead of the gate), its potential may also be limited to 10V, for example. FIG. 4b shows a detail of the upper part of FIG. 4a.

FIG. 5 shows a circuit diagram of a semiconductor device 500 according to an embodiment. The semiconductor device 500 comprises an insulated-gate field effect transistor 510 (IGFET) and a junction field effect transistor 520 (JFET). A drain region of the insulated-gate field effect transistor 510 and a drain region of the junction field effect transistor 520 are electrically connected (ohmic connection) to a drain contact interface 502 (e.g. drain pad or back side drain metallization) for connecting the semiconductor device 500 to an external load. Further, at least one source region of the insulated-gate field effect transistor 510 is electrically connected (ohmic connection) to a gate region of the junction field effect transistor 520. Additionally, a tap electrode structure 504 is electrically connected (ohmic connection) to a source region of the junction field effect transistor.

By implementing a JFET and an IGFET (e.g. metal-insulation-semiconductor field effect transistor MISFET, metal-oxide-semiconductor field effect transistor MOSFET or insulated-gate bipolar transistor IGBT) with a common drain and source of the IGFET connected to the gate of the JFET, the JFET pinches off when the drain voltage increases. Therefore, the maximal voltage at the source of the JFET may be kept low. Further, the voltage at the source of the JFET may be equal or proportional to the drain voltage in a conductive state of the IGFET. In this way, the signal obtained at the tap electrode structure may be used for various applications (e.g. for detecting overload situations or providing start-up currents).

For example, the at least one source region of the insulated-gate field effect transistor 510 is electrically connected (ohmic connection) to a gate region of the junction field effect transistor 520 by a resistive path implemented within the semiconductor substrate (e.g. by a resistive path between the internal body regions and the gate of the JFET) and/or outside the semiconductor substrate (e.g. by a source electrode structure or conductive material (metal) in a contact trench of the IGFET, which connects the source region and the body region and implements an ohmic connection between the source and the gate of the JFET, which may be the body region).

For example, the one or more source regions (e.g. all) of the insulated-gate field effect transistor 510 and the one or more gate regions (e.g. two neighboring compensation regions) of the junction field effect transistor 520 may be connected or connectable (ohmic connection) to a reference potential (e.g. ground). For example, the one or more source regions of the insulated-gate field effect transistor 510 and the one or more gate regions of the junction field effect transistor 520 may be connected to a source electrode structure of the semiconductor device 500 connected (ohmic connection) to a source contact interface (e.g. source pad). Further, one or more body regions (e.g. all) of the insulated-gate field effect transistor is electrically connected (ohmic connection) to the source terminal of the insulated-gate field effect transistor.

The IGFET 510 and the JFET 520 may be integrated on a semiconductor substrate as described above (e.g. FIG. 1 or FIG. 2) or below. The IGFET 510 may be a vertical electrical element arrangement as described in connection with FIG. 1 or 2, for example.

More details and aspects are mentioned in connection with the embodiments described above or below. The embodiment shown in FIG. 5 may comprise one or more optional additional features corresponding to one or more aspects mentioned in connection with the proposed concept or one or more embodiments described above (e.g. FIG. 1-4b) or below (e.g. FIG. 6-8).

Some embodiments relate to an electrical device comprising a semiconductor device according the described concept or an embodiment described above (e.g. FIG. 1, 2 or 5) or below. Further, the electrical device comprises a control circuit coupled to the tap electrode structure of the semiconductor device.

The control circuit may be implemented on the semiconductor substrate of the semiconductor device or may be a separate device connected to the semiconductor device (e.g. implemented in a common package or in separate packages).

The control circuit may be a processor, a microcontroller or an application-specific integrated circuit, for example.

The control circuit may be configured to switch or activate/deactivate the semiconductor device (e.g. the vertical electrical element arrangement or the insulated-gate field effect transistor of the semiconductor device). For example, the control circuit may be configured to control a switching or a deactivation of the semiconductor device based on a signal received through the tap electrode structure of the semiconductor device. For example, the control circuit may be configured to switch or deactivate the semiconductor device based on a comparison of a voltage occurring at the tap electrode structure of the semiconductor device with a predefined threshold voltage. For example, the semiconductor device or a vertical electrical element arrangement of the semiconductor device or an insulated-gate field effect transistor of the semiconductor device may be switched-off or deactivated, if a current or voltage detected at the tap electrode structure may be above a predefined threshold. For example, the control circuit knowns when the semiconductor device is in an on-state or conducting state. In this case, the control circuit may identify an overload situation, if the voltage at the tap electrode structure increases above a preset threshold voltage.

For example, the control circuit may be configured to provide a gate voltage to a gate electrode structure of the vertical electrical element arrangement of the semiconductor device (e.g. FIG. 1 or 2) or a gate electrode structure of the insulated-gate field effect transistor of the semiconductor device (e.g. FIG. 5).

More details and aspects are mentioned in connection with the embodiments described above or below. The electrical device may comprise one or more optional additional features corresponding to one or more aspects mentioned in connection with the proposed concept or one or more embodiments described above (e.g. FIG. 1-5) or below (e.g. FIG. 6-8).

FIG. 6 shows a schematic illustration of an electrical device 600 according to an embodiment. The electrical device 600 comprises a control circuit 610 and a semiconductor device 620. The implementation of the semiconductor device 620 is similar to the implementation of the semiconductor device shown in FIG. 5. A measurement input of the control circuit 610 is connected to a sense terminal (e.g. pad connected to the tap electrode structure) of the semiconductor device 620. Further, the control circuit may comprise a driver integrated circuit configured to provide a gate voltage to a gate contact (e.g. gate pad) of the semiconductor device 620 through an optional resistor 630. The semiconductor device 620 comprises a load transistor T_{load} implemented by the IGFET 510 and a sense transistor Tₛₑₙₛₑ implemented by the JFET 520. The one or more source regions of the IGFET 510 and the one or more gate regions (e.g. two neighboring compensation regions) of the JFET 520 may be connected or connectable to ground potential. The drain region of the IGFET 510 and a drain region of the JFET 520 are electrically connected or connectable to an external load.

As an example, FIG. 6 shows the application of a proposed structure comprising a load transistor and a monolithically integrated sense transistor in a circuit having a drive integrated circuit IC, wherein the sense transistor comprises approximately the same blocking capability as the load transistor, or blocks even more, for example. As both transistors are monolithically integrated and have a common drain terminal and edge termination, it may be possible to meet this requirement. As an equivalent circuit diagram, the sense transistor may be considered to be a normally-on JFET (in this case: n-channel). In one example, the p-gate of the sense-JFET is on the same potential as the source of the load transistor. The measuring input of the drive IC is connected to the source of the n-channel JFET. As soon as the potential of the source of the n-channel JFET increases above the threshold voltage of the transistor, the latter is pinched off and limits the voltage at the input of the IC to non-critical values, for example.

FIG. 6 shows an example of a circuit with an integrated sense transistor. The gate series resistor for the load transistor is optional. Protective measures for the gate of the load resistance, e.g., clamping with Z diodes and/or diodes onto the drain and/or onto the source, as well as other protective resistors, e.g., between gate and source to prevent a conductive load transistor in case of a failure of the control voltage, are optional and are not illustrated.

The circuit of FIG. 6 may be used to detect any overload occurrence at the load transistor as this does not require any particularly precise measurement using tolerances on the range of a few %, for example. If the current on-resistance of the load transistor is known which may, for example, be determined via its temperature, chip area, etc., the measurement of the drain voltage may, however, also be used to measure the load current flowing through the load transistor, for example.

Instead of the circuit shown in FIG. 6 with a so-called single-ended switching, a proposed structure may be employed in half-bridge arrangements as well. For example, it may be possible to also monitor the operating condition of the upper half-bridge transistors in a simple and efficient manner.

In superjunction technologies, the p- and n-columns may each be manufactured by masked implantations in which a doping species is implanted over an opening underneath which the other doping species is located. By adjusting the openings (e.g., instead of a large opening of the implantation mask, two or more smaller openings having no more than the same total opening and/or partial overlap of the p- and n-openings) or changing the distance between the p- and n-openings, the pinch-off voltage of the sense transistor may be different from the depletion voltage of the load transistor. This may mean that, via the design and without any technological changes, the voltage limitation of the sense transistor, or in other words the cut-off voltage of the JFET may be varied in many ways to meet requirements resulting from the system design.

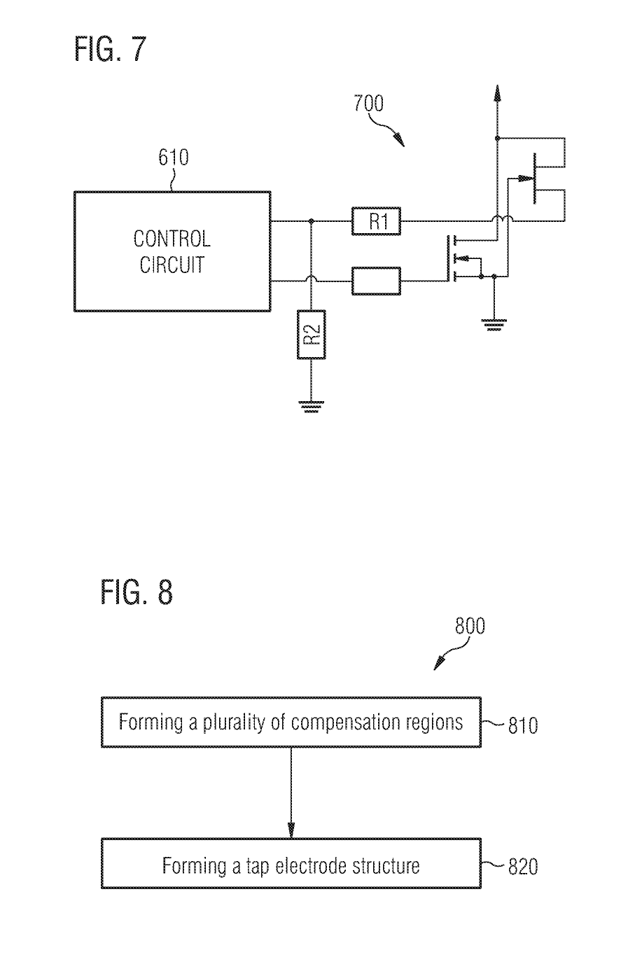

More details and aspects are mentioned in connection with the embodiments described above or below. The embodiment shown in FIG. 6 may comprise one or more optional additional features corresponding to one or more aspects mentioned in connection with the proposed concept or one or more embodiments described above (e.g. FIG. 1-5) or below (e.g. FIG. 7-8).

FIG. 7 shows a schematic illustration of an electrical device 700 according to an embodiment. The implementation of the electrical device 700 is similar to the implementation of the semiconductor device shown in FIG. 6. However, a voltage divider is arranged between the measurement input of the control circuit 610 and the sense terminal of the semiconductor device. The voltage divider comprises a first resistor R1 located between the measurement input of the control circuit 610 and the sense terminal of the semiconductor device and a second resistor R2 arranged between ground potential and a node between the measurement input of the control circuit 610 and the first resistor R1. The resistance of the first and second resistor may be selected so that a voltage occurring at the measurement input of the control circuit 610 is within a desired voltage range.

FIG. 7 shows an example of a circuit in which the potential of the sense output is fed to the measuring input via the voltage divider. In addition to the resistors R1 and/or R2, capacitors parallel to R2 (low-pass filtering) and/or to R1 (acceleration of the response) may be used.

In the embodiment shown in FIG. 7, the sense terminal is not directly connected to the measuring input of the drive IC but via. e.g., a voltage divider. In this case, it is possible to realize higher pinch-off voltages at the sense transistor as well, without overloading the drive IC. A possible application for such systems may be the control of the switching time of the load transistor.

An example for an application may be a flyback converter in which the load transistor is switched off. Then a high voltage is applied via the transformer during the energy transport (supply and reflected voltage) which falls then to supply voltage level, for example. Parasitics existing in the system may result in significant voltage undershoots (e.g. the voltage at the load transistor may fall close to 0V in extreme cases). If the load transistor is switched on in such a voltage minimum (so-called valley switching), the turn-on losses may be dramatically reduced. A proposed circuit may be used for accurate, rational detection of such valleys.

Another example for an application of a proposed circuit is in resonance circuits, as the current voltage condition of the switch may always be detected. For example, turning on the transistor may only be released if its drain voltage is below a certain value. Hence, the commutation of the body diode in the corresponding other half-bridge branch may be avoided, and therefore a considerable amount of switching losses may be saved and/or the robustness of the circuit and/or the electromagnetic compatibility EMC may be improved.

More details and aspects are mentioned in connection with the embodiments described above or below. The embodiment shown in FIG. 7 may comprise one or more optional additional features corresponding to one or more aspects mentioned in connection with the proposed concept or one or more embodiments described above (e.g. FIG. 1-6) or below (e.g. FIG. 8).

FIG. 8 shows a flow chart of a method for forming a semiconductor device according to an embodiment. The method 800 comprises forming 810 a plurality of compensation regions arranged in a semiconductor substrate. The compensation regions of the plurality of compensation regions comprise a first conductivity type. Further, a plurality of drift region portions of a drift region of a vertical electrical element arrangement are arranged in the semiconductor substrate. The drift region comprises a second conductivity type. Additional, drift region portions of the plurality of drift region portions and compensation regions of the plurality of compensation regions are arranged alternatingly in a lateral direction. Further, the method 800 comprises forming 820 a tap electrode structure in contact with a tap portion of the drift region at a front side surface of the semiconductor substrate. The tap portion is located laterally between two neighboring compensation regions of the plurality of compensation regions. Additionally, the tap electrode structure is implemented without resistive connection to the plurality of compensation regions

By implementing a tap contact to a portion of a drift region of a vertical electrical element arrangement between two compensation regions, a voltage or current can be tapped at the front side surface of the semiconductor substrate.

More details and aspects are mentioned in connection with the embodiments described above or below. The embodiment shown in FIG. 8 may comprise one or more optional additional features corresponding to one or more aspects mentioned in connection with the proposed concept or one or more embodiments described above (e.g. FIG. 1-7) or below.

Some embodiments relate to a compensation transistor with voltage measurement possibility. For example, in a number of measuring and monitoring tasks in switched-mode power supplies, a direct measurement of the forward voltage of power transistors may be enabled. Thus, further peripheral devices may be saved in the systems, which may result in reduced cost and losses as well as more compact structures. According to an aspect of an implementation of a voltage measurement between source and drain, in the normal on-state range of a power transistor, only a few 10 . . . 10 mV and/or a voltage of a few volts may be applied, while several 100V, sometimes even more than 1000V, may be applied in the off-state case. The interesting measuring range may be limited to a range of a few volts. As soon as higher voltages are applied at the switched-on transistor outside the switching transient, this may mean an inadmissible overload that may require a response.

The proposed concept may relate to a system to determine the operating situation of a load transistor (e.g. a super junction transistor) via a monolithically integrated, normally-on sense transistor and to determine the drain potential of the load transistor in operation, for example.

An aspect relates to a voltage measuring and limiting structure in a compensation device and the use of this structure in an electronic system, for example, in a switching-mode power supply, to detect the current level and, for example, to detect overload occurrences. In this respect, the column structure of compensation devices may be used which are depleted laterally at comparably low voltages, for example. Stripe cells, for example, stripe-shaped compensation areas and transistors having a low on resistance R_{DS,on}*A in relation to the surface, may be used, as these transistors may already deplete the semiconductor areas in the area of the pn-compensation columns at comparably low drain source voltages.

Example embodiments may further provide a computer program having a program code for performing one of the above methods, when the computer program is executed on a computer or processor. A person of skill in the art would readily recognize that acts of various above-described methods may be performed by programmed computers. Herein, some example embodiments are also intended to cover program storage devices, e.g., digital data storage media, which are machine or computer readable and encode machine-executable or computer-executable programs of instructions, wherein the instructions perform some or all of the acts of the above-described methods. The program storage devices may be, e.g., digital memories, magnetic storage media such as magnetic disks and magnetic tapes, hard drives, or optically readable digital data storage media. Further example embodiments are also intended to cover computers programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. It will thus be appreciated that those skilled in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and embodiments of the disclosure, as well as specific examples thereof, are intended to encompass equivalents thereof.

It should be appreciated by those skilled in the art that any block diagrams herein represent conceptual views of illustrative circuitry embodying the principles of the disclosure. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

Furthermore, the following claims are hereby incorporated into the Detailed Description, where each claim may stand on its own as a separate embodiment. While each claim may stand on its own as a separate embodiment, it is to be noted that—although a dependent claim may refer in the claims to a specific combination with one or more other claims—other embodiments may also include a combination of the dependent claim with the subject matter of each other dependent or independent claim. Such combinations are proposed herein unless it is stated that a specific combination is not intended. Furthermore, it is intended to include also features of a claim to any other independent claim even if this claim is not directly made dependent to the independent claim.

It is further to be noted that methods disclosed in the specification or in the claims may be implemented by a device having means for performing each of the respective acts of these methods.

Further, it is to be understood that the disclosure of multiple acts or functions disclosed in the specification or claims may not be construed as to be within the specific order. Therefore, the disclosure of multiple acts or functions will not limit these to a particular order unless such acts or functions are not interchangeable for technical reasons. Furthermore, in some embodiments a single act may include or may be broken into multiple sub acts. Such sub acts may be included and part of the disclosure of this single act unless explicitly excluded.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a plurality of compensation regions arranged in a semiconductor substrate, the compensation regions of the plurality of compensation regions comprising a first conductivity type; and
a plurality of drift region portions of a drift region of a vertical electrical element arrangement arranged in the semiconductor substrate, the drift region comprising a second conductivity type; and
a tap electrode structure in contact with a tap portion of the drift region at a front side surface of the semiconductor substrate,
wherein drift region portions of the plurality of drift region portions and compensation regions of the plurality of compensation regions are arranged alternatingly in a lateral direction,
wherein the tap portion is located laterally between two neighboring compensation regions of the plurality of compensation regions,
wherein the tap electrode structure is implemented without resistive connection to the plurality of compensation regions.

2. The semiconductor device of claim 1, wherein the tap portion of the drift region and the neighboring compensation regions of the plurality of compensation regions are implemented so that a voltage occurring at the tap electrode structure in a blocking state of the vertical electrical element arrangement is less than 5% of a blocking voltage applied in the blocking state.

3. The semiconductor device of claim 1, wherein a lateral width of a drift region portion of the plurality of drift region portions measured at a measurement depth of half a depth of a compensation region of the plurality of compensation regions differs from a lateral width of the tap portion measured at the measurement depth by more than 10% of the lateral width of the tap portion measured at the measurement depth.

4. The semiconductor device of claim 1, wherein a lateral width of a drift region portion of the plurality of drift region portions measured at the front side surface of the semiconductor substrate differs from a lateral width of the tap portion measured at the front side surface of the semiconductor substrate by more than 10% of the lateral width of the tap portion measured at the front side surface of the semiconductor substrate.

5. The semiconductor device of claim 1, wherein a doping concentration within a drift region portion of the plurality of drift region portions measured at a source depth equal to a depth of a source doping region of the vertical electrical element arrangement is larger than a doping concentration within the tap portion measured at the source depth.

6. The semiconductor device of claim 1, further comprising a gate electrode structure electrically connected to one or more gates of the vertical electrical element arrangement, wherein the one or more gates are configured to control a current through the plurality of drift region portions of the vertical electrical element arrangement.

7. The semiconductor device of claim 6, wherein the vertical electrical element arrangement is implemented without a gate for controlling a current through the tap portion.

8. The semiconductor device of claim 6, wherein at least a part of the tap electrode structure is located below at least a portion of the gate electrode structure of the vertical electrical element arrangement.

9. The semiconductor device of claim 1, wherein the tap electrode structure is electrically connected to a contact interface of the semiconductor device at a front side of the semiconductor device.

10. The semiconductor device of claim 1, wherein the tap electrode structure is electrically insulated from a source electrode structure of the vertical electrical element arrangement and electrically insulated from a gate electrode structure of the vertical electrical element arrangement.

11. The semiconductor device of claim 1, wherein the plurality of compensation regions and the plurality of drift region portions of the vertical electrical element arrangement are stripe-shaped.

12. The semiconductor device of claim 1, wherein the vertical electrical element arrangement is a vertical diode arrangement or a vertical transistor arrangement.

13. The semiconductor device of claim 1, wherein the vertical electrical element arrangement has a blocking voltage of more than 30V.

14. An electrical device, comprising:
the semiconductor device of claim 1; and
a control circuit coupled to the tap electrode structure of the semiconductor device.

15. The electrical device of claim 14, wherein the control circuit is configured to provide a gate voltage to a gate electrode structure of the vertical electrical element arrangement of the semiconductor device.

16. The electrical device according to claim 14, wherein the control circuit is configured to control a switching or a deactivation of the semiconductor device based on a signal received from the tap electrode structure of the semiconductor device.

17. The electrical device according to claim 14, wherein the control circuit is configured to switch or deactivate the semiconductor device based on a comparison of a voltage occurring at the tap electrode structure of the semiconductor device with a predefined threshold voltage.

18. A semiconductor device, comprising:
an insulated-gate field effect transistor; and
a junction field effect transistor,
wherein a drain region of the insulated-gate field effect transistor and a drain region of the junction field effect transistor are electrically connected to a drain contact interface for connecting the semiconductor device to an external load,
wherein at least one source region of the insulated-gate field effect transistor is electrically connected to a gate region of the junction field effect transistor,
wherein a tap electrode structure is electrically connected to a source region of the junction field effect transistor.

19. The semiconductor device of claim 18, wherein the at least one source region of the insulated-gate field effect transistor and the gate region of the junction field effect transistor are connected or connectable to a reference potential.

20. An electrical device, comprising:
the semiconductor device of claim 18; and
a control circuit coupled to the tap electrode structure of the semiconductor device.

21. The electrical device of claim 20, wherein the control circuit is configured to provide a gate voltage to a gate electrode structure of the insulated-gate field effect transistor of the semiconductor device.

22. The electrical device of claim 20, wherein the control circuit is configured to control a switching or a deactivation of the semiconductor device based on a signal received from the tap electrode structure of the semiconductor device.

23. The electrical device of claim 20, wherein the control circuit is configured to switch or deactivate the semiconductor device based on a comparison of a voltage occurring at the tap electrode structure of the semiconductor device with a predefined threshold voltage.

24. A method for forming a semiconductor device, the method comprising:
forming a plurality of compensation regions arranged in a semiconductor substrate, the compensation regions of the plurality of compensation regions comprising a first conductivity type, a plurality of drift region portions of a drift region of a vertical electrical element arrangement being arranged in the semiconductor substrate, the drift region comprising a second conductivity type, drift region portions of the plurality of drift region portions and compensation regions of the plurality of compensation regions being arranged alternatingly in a lateral direction; and
forming a tap electrode structure in contact with a tap portion of the drift region at a front side surface of the semiconductor substrate, the tap portion being located laterally between two neighboring compensation regions of the plurality of compensation regions, the tap electrode structure being implemented without resistive connection to the plurality of compensation regions.
